(19) United States
(12) Patent Application Publication
(10) Pub. No.: US 2026/0056038 A1
(43) Pub. Date: Feb. 26, 2026

(54) MAGNETIC SENSOR UNIT

(71) Applicant: HAMAMATSU PHOTONICS K.K., Hamamatsu-shi (JP)

(72) Inventor: Takeshi ENDO, Shizuoka (JP)

(73) Assignee: HAMAMATSU PHOTONICS K.K., Hamamatsu-shi (JP)

(21) Appl. No.: 19/304,427

(22) Filed: Aug. 19, 2025

(30) Foreign Application Priority Data
Aug. 22, 2024 (JP) 2024-141054

(51) Int. Cl. G01D 11/30; G01D 11/24; G01R 33/26

(52) U.S. Cl. CPC G01D 11/30; G01D 11/245; G01R 33/26

(57) ABSTRACT

A magnetic sensor unit includes a magnetic sensor and a holding member that detachably holds the magnetic sensor. A first engaging portion formed by a recess is formed on a side surface of the magnetic sensor. The holding member includes a base portion and an extension portion extending from the base portion, the extension portion being formed with a second engaging portion formed by a protrusion corresponding to the recess. The magnetic sensor is detachably held by the holding member by the second engaging portion being engaged with the first engaging portion.

### TECHNICAL FIELD

An aspect of the present disclosure relates to a magnetic sensor unit.

### BACKGROUND

For example, Japanese Unexamined Patent Publication No. 2020-146408 describes a magnetic field detection device including a housing (headgear) that is worn on the head of a subject, and a plurality of magnetic sensors that detect magnetic field vectors emitted from the head of the subject. In the device described in Japanese Unexamined Patent Publication No. 2020-146408, each magnetic sensor is fixed to the headgear by a sensor fixing portion including a sensor fixing pin (FIG. 15). During fixing, the sensor fixing pin is caught on the magnetic sensor, thereby fixing the magnetic sensor to the headgear. In addition, Japanese Unexamined Patent Publication No. 2020-168138 describes a configuration in which a magnetic sensor is fixed using a screw (FIG. 5).

The magnetic sensor described above is required to measure a magnetic field with high sensitivity. Since the magnetic field attenuates in proportion to the square of the distance, placing the magnetic sensor as close as possible to a measurement target (for example, a subject) is required. In this regard, in the fixing method in which the magnetic sensor is sandwiched as disclosed in Japanese Unexamined Patent Publication No. 2020-146408, the magnetic sensor may become spaced apart from the measurement target, and a magnetic field may not be measurable with high sensitivity. In addition, in the devices described above, for example, a number of the magnetic sensors are attached to an attachment member such as a headgear. The headgear may be replaced to match the shape of the measurement target, and in that case, the magnetic sensor needs to be transferred to a different headgear. Therefore, the magnetic sensor is required to be easily attachable and detachable.

### SUMMARY

Therefore, an object of one aspect of the present disclosure is to provide a magnetic sensor unit that enables a magnetic sensor to be brought close to a measurement target and that enables the magnetic sensor to be easily attached and detached.

A magnetic sensor unit according to one aspect of the present disclosure is [1] “a magnetic sensor unit including: a magnetic sensor; and a holding member that detachably holds the magnetic sensor. A first engaging portion formed by at least one of a recess and a protrusion is formed on an outer surface of the magnetic sensor. The holding member includes a base portion and an extension portion extending from the base portion, the extension portion being formed with a second engaging portion formed by at least one of a protrusion corresponding to the recess and a recess corresponding to the protrusion. The magnetic sensor is detachably held by the holding member by the second engaging portion being engaged with the first engaging portion.”

In the magnetic sensor unit, the first engaging portion formed by at least one of the recess and the protrusion is formed on the outer surface of the magnetic sensor, and the second engaging portion formed by at least one of the protrusion corresponding to the recess of the first engaging portion and the recess corresponding to the protrusion of the first engaging portion is formed in the extension portion of the holding member. Furthermore, the magnetic sensor is detachably held by the holding member by the second engaging portion being engaged with the first engaging portion. By adopting such a holding structure, the magnetic sensor can be brought closer to a measurement target, for example, compared to when the magnetic sensor is held by being sandwiched between the holding members. In addition, since the magnetic sensor is detachably held by the engagement between the first engaging portion formed on the outer surface of the magnetic sensor and the second engaging portion formed in the extension portion, the magnetic sensor can be easily attached and detached. Therefore, according to the magnetic sensor unit, the magnetic sensor can be brought close to the measurement target, and the magnetic sensor can be easily attached and detached.

A magnetic sensor unit according to one aspect of the present disclosure may be [2] “the magnetic sensor unit according to [1], in which the holding member further includes a guide portion extending from the base portion, and the magnetic sensor is guided by the guide portion while the magnetic sensor is being attached to the holding member.” In this case, the magnetic sensor can be easily attached to the holding member.

A magnetic sensor unit according to one aspect of the present disclosure may be [3] “the magnetic sensor unit according to [2], in which the guide portion is disposed to interpose the magnetic sensor between the extension portion and the guide portion.” In this case, the magnetic sensor can be more easily attached to the holding member.

A magnetic sensor unit according to one aspect of the present disclosure may be [4] “the magnetic sensor unit according to [2] or [3], in which a length by which the guide portion extends from the base portion is longer than a length by which the extension portion extends from the base portion. ” In this case, the magnetic sensor can be easily attached to the holding member.

A magnetic sensor unit according to one aspect of the present disclosure may be [5] “the magnetic sensor unit according to any one of [1] to [4], in which at least one of the first engaging portion and the second engaging portion is formed with an inclined surface that guides the first engaging portion or the second engaging portion while the magnetic sensor is being attached to the holding member and/or while the magnetic sensor is being removed from the holding member.” In this case, the magnetic sensor can be easily attached to or removed from the holding member. Incidentally, in this specification, “A and/or B” means “at least one of A and B.”

A magnetic sensor unit according to one aspect of the present disclosure may be [6] “the magnetic sensor unit according to any one of [1] to [5], in which the magnetic sensor is formed in a rectangular shape when viewed in an extending direction of the extension portion, a pair of the extension portions, a pair of the first engaging portions, and a pair of the second engaging portions are provided, and the pair of extension portions are disposed to interpose the magnetic sensor between the pair of extension portions in a direction perpendicular to long sides of the magnetic sensor.” In this case, the shape of the magnetic sensor unit when viewed in the extending direction of the extension portion can be made compact.

A magnetic sensor unit according to one aspect of the present disclosure may be [7] “the magnetic sensor unit according to any one of [1] to [5], in which the magnetic sensor is formed in a rectangular shape when viewed in an extending direction of the extension portion, a pair of the extension portions, a pair of the first engaging portions, and a pair of the second engaging portions are provided, and the pair of extension portions are disposed to interpose the magnetic sensor between the pair of extension portions in a direction perpendicular to short sides of the magnetic sensor.” In this case, when a plurality of the magnetic sensor units are aligned along a direction parallel to the short sides of the magnetic sensor, the dead space can be reduced to improve the disposition efficiency.

A magnetic sensor unit according to one aspect of the present disclosure may be [8] “the magnetic sensor unit according to any one of [1] to [5], in which the magnetic sensor is formed in a square shape or a rectangular shape when viewed in an extending direction of the extension portion, four each of the extension portions, the first engaging portions, and the second engaging portions are provided, and the four extension portions are disposed to face four respective outer surfaces of the magnetic sensor when viewed in the extending direction.” In this case, the magnetic sensor can be stably held by the holding member.

A magnetic sensor unit according to one aspect of the present disclosure may be [9] “the magnetic sensor unit according to any one of [1] to [5], in which the magnetic sensor is formed in a square shape or a rectangular shape when viewed in an extending direction of the extension portion, a pair of the extension portions, a pair of the first engaging portions, and a pair of the second engaging portions are provided, the pair of extension portions are disposed to interpose the magnetic sensor between the pair of extension portions in a first direction perpendicular to the extending direction, the holding member further includes a pair of guide portions extending from the base portion, the magnetic sensor is guided by the pair of guide portions while the magnetic sensor is being attached to the holding member, and the pair of guide portions are disposed to interpose the magnetic sensor between the pair of guide portions in a second direction perpendicular to the extending direction and the first direction.” In this case, since the pair of extension portions are disposed to interpose the magnetic sensor therebetween, the magnetic sensor can be reliably held by the holding member, and since the pair of guide portions are disposed to interpose the magnetic sensor therebetween, the magnetic sensor can be easily attached to the holding member.

A magnetic sensor unit according to one aspect of the present disclosure may be [10] “the magnetic sensor unit according to any one of [1] to [9], in which an engaging position of the first engaging portion and the second engaging portion is located on a base end side of the magnetic sensor in an extending direction of the extension portion.” In this case, the extension portions can be shortened, and the magnetic sensor unit can be made compact.

A magnetic sensor unit according to one aspect of the present disclosure may be [11] “the magnetic sensor unit according to any one of [1] to [9], in which an engaging position of the first engaging portion and the second engaging portion is located on a tip side of the magnetic sensor in an extending direction of the extension portion.” In this case, the extension portions can be lengthened, and the magnetic sensor can be stably held by the holding member.

A magnetic sensor unit according to one aspect of the present disclosure may be [12] “the magnetic sensor unit according to any one of [1] to [11], in which a plurality of the first engaging portions are formed in the magnetic sensor, and the second engaging portion is selectively engaged with any one of the plurality of first engaging portions.” In this case, the position at which the magnetic sensor is held by the holding member can be adjusted by changing the first engaging portion with which the second engaging portion is engaged.

A magnetic sensor unit according to one aspect of the present disclosure may be [13] “the magnetic sensor unit according to [12], in which the plurality of first engaging portions are aligned along a direction perpendicular to an extending direction of the extension portion.” In this case, the position at which the magnetic sensor is held by the holding member can be adjusted in the direction perpendicular to the extending direction of the extension portion.

A magnetic sensor unit according to one aspect of the present disclosure may be [14] “the magnetic sensor unit according to [12], in which the plurality of first engaging portions are aligned along a direction parallel to an extending direction of the extension portion.” In this case, the position at which the magnetic sensor is held by the holding member can be adjusted in the direction parallel to the extending direction of the extension portion.

A magnetic sensor unit according to one aspect of the present disclosure may be [15] “the magnetic sensor unit according to any one of [1] to [14], in which a plurality of the second engaging portions are formed in the extension portion, and the first engaging portion is selectively engaged with any one of the plurality of second engaging portions.” In this case, the position at which the magnetic sensor is held by the holding member can be adjusted by changing the second engaging portion with which the first engaging portion is engaged.

A magnetic sensor unit according to one aspect of the present disclosure may be [16] “the magnetic sensor unit according to any one of [1] to [15], in which the holding member holds the magnetic sensor such that a gap is provided between the extension portion and the magnetic sensor.” In this case, the magnetic sensor can be cooled by allowing cooling air to flow through the gap.

According to the present disclosure, it is possible to provide the magnetic sensor unit that enables the magnetic sensor to be brought close to the measurement target and that enables the magnetic sensor to be easily attached and detached.

### BRIEF DESCRIPTION OF THE DRAWINGS

FIG. 1 is a configuration view of a sensor module in which a plurality of magnetic sensor units are attached to an attachment member.

FIG. 2 is a plan view of the attachment member.

FIG. 3 is a perspective view of a magnetic sensor constituting the magnetic sensor unit.

FIG. 4A is a perspective view of a holding member constituting the magnetic sensor unit, and FIG. 4B is a plan view of the holding member.

FIG. 5 is a cross-sectional view of the magnetic sensor unit.

FIG. 6A is a cross-sectional view of a magnetic sensor unit according to a comparative example, and FIG. 6B is a cross-sectional view of a magnetic sensor unit according to a first modification example.

FIG. 7A shows a side view and a plan view of a magnetic sensor unit according to a second modification example, FIG. 7B shows a side view and a plan view of a magnetic sensor unit according to a third modification example, and FIG. 7C shows a side view and a plan view of a magnetic sensor unit according to a fourth modification example.

FIG. 8A shows a side view and a plan view of a magnetic sensor unit according to a fifth modification example, and FIG. 8B shows a side view and a plan view of a magnetic sensor unit according to a sixth modification example.

FIG. 9A shows a plan view of the magnetic sensor unit according to the sixth modification example, FIG. 9B shows a plan view of the magnetic sensor unit according to the fifth modification example, FIG. 9C shows a plan view of the magnetic sensor unit according to the second modification example FIG. 9D shows a plan view of the magnetic sensor unit according to the third modification example, and FIGS. 9E and 9F show plan views of the magnetic sensor units according to the fourth modification example.

FIG. 10A shows a side view and a plan view of a magnetic sensor unit according to a seventh modification example, and FIG. 10B is a side view and a plan view of a magnetic sensor unit according to an eighth modification example.

FIG. 11A shows a side view and a plan view of a magnetic sensor unit according to a ninth modification example, and FIG. 11B is a side view of another attached state of the magnetic sensor unit according to the ninth modification example.

FIG. 12A is a side view of a magnetic sensor unit according to a tenth modification example, and FIG. 12B is a side view of a magnetic sensor unit according to an eleventh modification example.

FIG. 13A is a side view of a magnetic sensor unit according to a twelfth modification example, and FIG. 13B is a side view of a magnetic sensor unit according to a thirteenth modification example.

FIG. 14 is a cross-sectional view of a magnetic sensor unit according to a fourteenth modification example.

### DETAILED DESCRIPTION

Hereinafter, an embodiment of the present disclosure will be described in detail with reference to the drawings. In the following description, the same reference signs are used for the same or corresponding elements, and duplicate descriptions will be omitted.

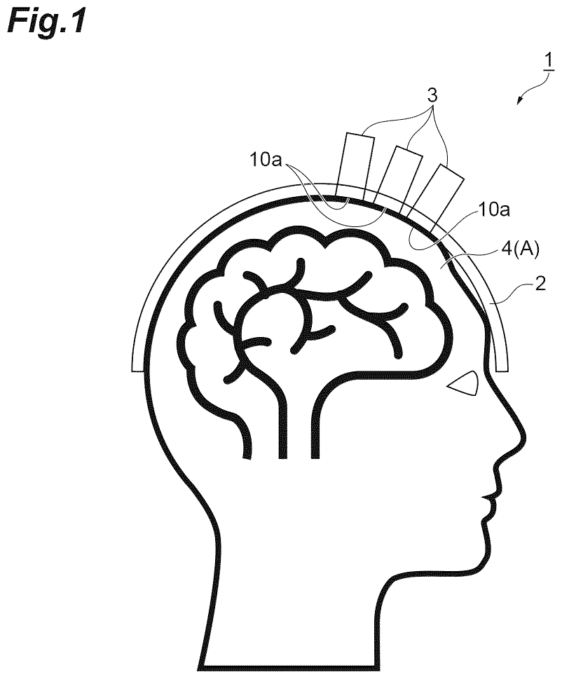

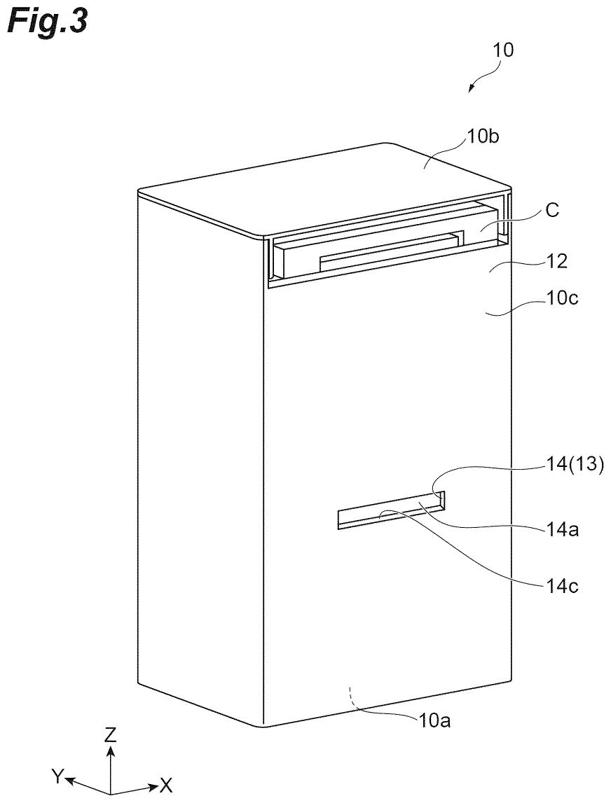

As shown in FIG. 1, a sensor module 1 according to an embodiment includes an attachment member 2 and a plurality of magnetic sensor units 3 attached to the attachment member 2. The sensor module 1 is used to measure a magnetic field generated in a measurement target A. The measurement target A is, for example, a human, and in this case, the sensor module 1 is used for biomagnetic field measurement to measure a magnetic field generated in a human (living body). In this example, the measurement target A is the brain (head 4) of a human, and the sensor module 1 is used as a magnetoencephalograph that measures a magnetic field generated in the brain (magnetoencephalography (MEG)). The sensor module 1 is attached to the head 4 of a human, and a magnetic field is measured by a magnetic sensor 10 (FIG. 3) included in the magnetic sensor unit 3.

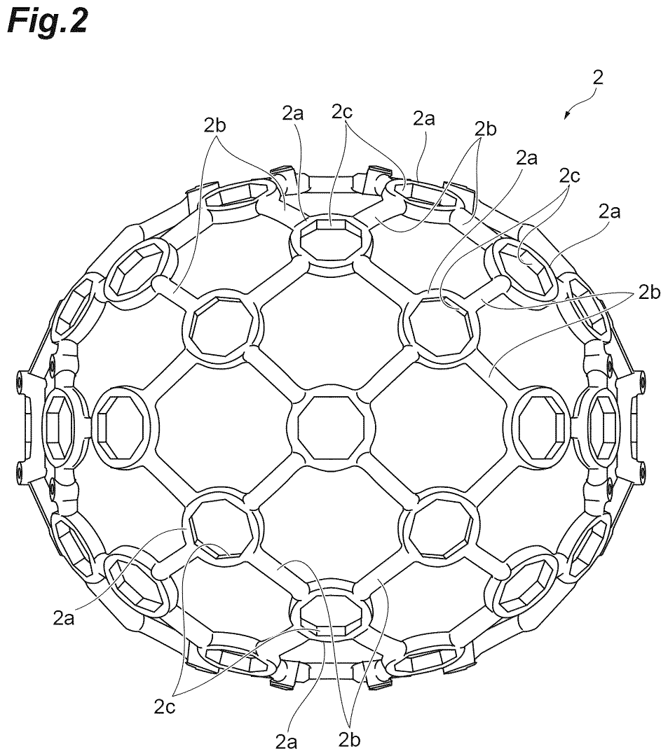

As shown in FIGS. 1 and 2, the attachment member 2 is configured to be attachable to the measurement target A, and can be attached to or detached from the measurement target A. In this example, the attachment member 2 is a headgear (helmet) to be worn on the head 4, and is formed in a hemispherical shape corresponding to the head 4.

The attachment member 2 includes a plurality of attachment portions 2a and a plurality of connecting portions 2b connecting the attachment portions 2a. The attachment portion 2a is formed, for example, in a substantially circular shape, and an attachment hole 2c to which the magnetic sensor unit 3 is attached is formed in the attachment portion 2a. The attachment hole 2c is formed, for example, in an octagonal shape. The magnetic sensor unit 3 is attached to the attachment portion 2a by fitting the magnetic sensor unit 3 into the attachment hole 2c.

The plurality of attachment portions 2a are disposed, for example, in a predetermined disposition pattern over the entirety of the attachment member 2. In this example, the plurality of attachment portions 2a are disposed in alignment at equal intervals in each of a first direction extending along a hemispherical surface and a second direction extending along the hemispherical surface and intersecting the first direction. The attachment portions 2a adjacent to each other in the first direction are connected by the connecting portion 2b extending along the first direction, and the attachment portions 2a adjacent to each other in the second direction are connected by the connecting portion 2b extending in the second direction.

As shown in FIGS. 3 to 5, the magnetic sensor unit 3 includes the magnetic sensor 10 and a holding member 20 that detachably holds the magnetic sensor 10. The magnetic sensor unit 3 is attached to the attachment portion 2a (attachment hole 2c) of the attachment member 2. More specifically, by fitting a base portion 21 of the holding member 20 to be described later, which has a circular shape, into the attachment hole 2c, the magnetic sensor unit 3 is attached to the attachment portion 2a such that a measurement surface 10a of the magnetic sensor 10 to be described later faces the measurement target A. In the attached state, the magnetic sensor 10 protrudes from the attachment member 2 toward the side opposite the measurement target A. The magnetic sensor unit 3 is removable from the attachment portion 2a, and can be attached to and detached from the attachment member 2. Hereinafter, in the following description, focusing on one magnetic sensor unit 3, in the magnetic sensor unit 3, a direction perpendicular to the measurement surface 10a is defined as a Z direction, a direction perpendicular to the Z direction is defined as an X direction, and a direction perpendicular to the X direction and the Z direction is defined as a Y direction.

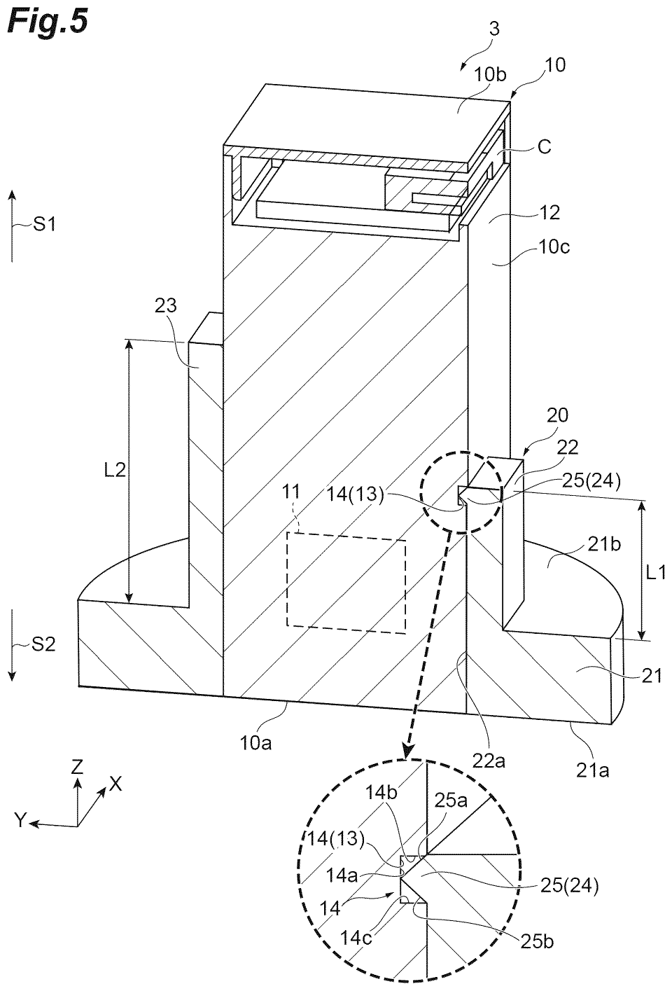

The magnetic sensor 10 is, for example, an optically pumped magnetometer (OPM). The magnetic sensor 10 includes, for example, a cell 11 in which gas containing an alkali metal is sealed, and a housing 12 that houses the cell 11 (FIG. 5). Various components other than the cell 11 constituting the magnetic sensor 10 may be housed in the housing 12. The components are, for example, a light source that outputs laser light, a photodetector, and the like to be described later. FIG. 5 is a cross-sectional view; however, the internal structure of the housing 12 is shown in a simplified manner, and the components other than the cell 11 are not shown (the housing 12 is actually formed in a box shape). In FIG. 5, the disposition position of the cell 11 is indicated by a dashed line.

During measurement, for example, in a state in which the inside of the cell 11 is filled with alkali metal vapor, circularly polarized laser light passes through the cell 11, and accordingly, the alkali metal vapor inside the cell 11 is brought into a spin-polarized state by optical pumping (optical excitation). The laser light that has passed through the cell 11 is detected by the photodetector. The intensity of the laser light detected by the photodetector changes according to the spin-polarized state of the alkali metal vapor inside the cell 11. Here, the spin-polarized state of the alkali metal vapor inside the cell 11 changes under the influence of the magnetic field of the measurement target A. Therefore, a change in the magnetic field of the measurement target A can be detected based on the intensity of the detected laser light.

As shown in FIGS. 3 and 5, the magnetic sensor 10 (housing 12) is formed in a rectangular parallelepiped shape, and is formed in a rectangular shape when viewed in the Z direction. An outer surface of the magnetic sensor 10 is formed by an outer surface of the housing 12. In this example, a length of the magnetic sensor 10 along the Z direction is longer than each of a length of the magnetic sensor 10 along the X direction and a length of the magnetic sensor 10 along the Y direction. The magnetic sensor 10 has the measurement surface 10a (bottom surface); a top surface 10b on the side opposite the measurement surface 10a; and a side surface 10c connected to the measurement surface 10a and the top surface 10b. The measurement surface 10a, the top surface 10b, and the side surface 10c constitute the outer surface of the magnetic sensor 10.

The measurement surface 10a is a surface facing the measurement target A during measurement, and in this example, is a flat surface perpendicular to the Z direction. The measurement surface 10a is a surface of the outer surface of the magnetic sensor 10 that is in proximity to the cell 11. For example, a distance from the measurement surface 10a to the cell 11 is shorter than a distance from the top surface 10b to the cell 11. A connector C into which a wiring (not shown) is inserted is provided at an end portion on the top surface 10b side of the magnetic sensor 10. The wiring is electrically connected to the magnetic sensor 10 at the connector C.

The side surface 10c is a surface extending along the Z direction, and in this example, is a flat surface perpendicular to the Y direction. A first engaging portion 13 is formed on the side surface 10c. In this example, the first engaging portion 13 is formed by a recess 14 (groove portion) extending along the X direction. In a cross section perpendicular to the X direction (an extending direction of the recess 14), the recess 14 is formed in a rectangular shape. The recess 14 has a bottom surface 14a and side surfaces 14b and 14c. The bottom surface 14a is a flat surface perpendicular to the Y direction, and the side surfaces 14b and 14c are flat surfaces facing each other in the Z direction. In this example, the recess 14 is disposed in a middle portion of the side surface 10c in the X direction, and is disposed slightly below the center of the side surface 10c in the Z direction.

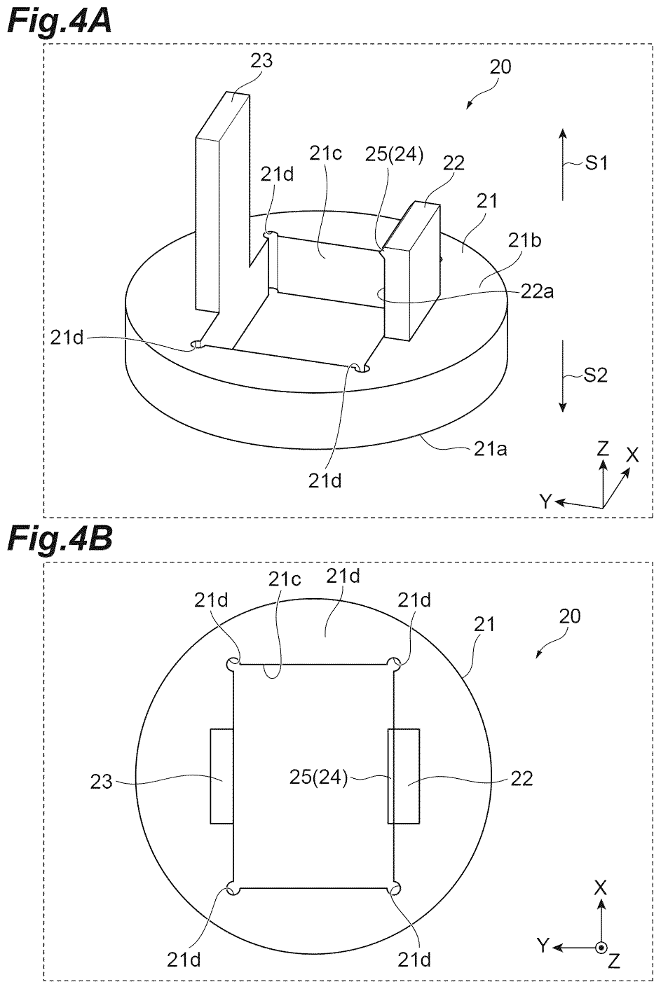

As shown in FIGS. 4A, 4B, and 5, the holding member 20 includes the base portion 21, an extension portion 22, and a guide portion 23. The holding member 20 is integrally formed from, for example, a resin material or a non-magnetic metal material. The holding member 20 can be formed, for example, by a 3D printer, cutting, or injection molding.

The base portion 21 is formed in a circular plate shape, and has a surface 21a on one side in the Z direction and a surface 21b on the side opposite the surface 21a. During measurement, the surface 21a faces the measurement target A. An opening portion 21c is formed in a central portion of the base portion 21. In this example, the opening portion 21c is formed in a rectangular shape having long sides parallel to the X direction. The opening portion 21c is formed in a shape corresponding to (in this example, coinciding with) the outer shape of the magnetic sensor 10 when viewed in the Z direction, and the magnetic sensor 10 can be disposed in the opening portion 21c. A relief portion 21d is formed at each corner of the opening portion 21c. The relief portion 21d is formed, for example, during cutting, but may not be formed.

The extension portion 22 is formed in a rectangular plate shape, and extends straight along the Z direction from the surface 21b of the base portion 21 toward the side opposite the measurement target A. The extension portion 22 is disposed on one side of the opening portion 21c in the Y direction when viewed in the Z direction (an extending direction of the extension portion 22). In this example, the extension portion 22 is disposed along an edge of the opening portion 21c in the Y direction. The extension portion 22 is disposed at a position corresponding to a middle portion of the opening portion 21c in the X direction. Hereinafter, in the following description, a tip side of the extension portion 22 is defined as a first side S1, and the side opposite the first side S1 is defined as a second side S2. The second side S2 is the measurement surface 10a side.

A second engaging portion 24 is formed at a tip portion of the extension portion 22. In this example, the second engaging portion 24 is formed by a protrusion 25 formed on a surface 22a of the extension portion 22. The surface 22a is a surface on the one side of the extension portion 22 in the Y direction, and is a surface facing the side surface 10c of the magnetic sensor 10 in a state in which the magnetic sensor 10 is attached to the holding member 20. The protrusion 25 extends along the X direction, and is provided over the entirety of the extension portion 22 in the X direction.

The protrusion 25 is formed in a shape corresponding to the recess 14 constituting the first engaging portion 13 (for example, a shape in which the protrusion 25 can enter the recess 14 and be engaged with the recess 14). In this example, the protrusion 25 has an inclined surface 25a on the first side S1, and an inclined surface 25b located on the second side S2 with respect to the inclined surface 25a. The inclined surface 25a is inclined toward the second side S2 as the inclined surface 25a approaches a tip side of the protrusion 25. The inclined surface 25b is inclined toward the first side S1 as the inclined surface 25b approaches the tip side of the protrusion 25. The protrusion 25 is formed in a triangular shape in a cross section perpendicular to the X direction (an extending direction of the protrusion 25).

As the protrusion 25 enters the recess 14, the protrusion 25 (second engaging portion 24) is engaged with the recess 14 (first engaging portion 13), and the magnetic sensor 10 is attached to the holding member 20. During the attachment, for example, the magnetic sensor 10 is moved from the first side S1 toward the second side S2, and is inserted between the extension portion 22 and the guide portion 23, and the recess 14 approaches the protrusion 25. Then, an opening edge on the side surface 14c side of the recess 14 slides on the inclined surface 25b of the protrusion 25, so that the protrusion 25 enters the recess 14 while the recess 14 is guided by the inclined surface 25b. During removal, the magnetic sensor 10 is moved toward the first side S1, and the opening edge on the side surface 14c side of the recess 14 slides on the inclined surface 25b of the protrusion 25, so that the protrusion 25 comes out of the recess 14 while the recess 14 is guided by the inclined surface 25b.

The guide portion 23 is formed in a rectangular plate shape, and extends straight along the Z direction from the surface 21b of the base portion 21. The guide portion 23 is disposed on the other side of the opening portion 21c in the Y direction (on the side opposite the extension portion 22) to face the extension portion 22 with the opening portion 21c interposed therebetween when viewed in the Z direction. The guide portion 23 is disposed to interpose (sandwich) the magnetic sensor 10 between the extension portion 22 and the guide portion 23 in a state in which the magnetic sensor 10 is attached to the holding member 20. In this example, the guide portion 23 is disposed along an edge of the opening portion 21c in the Y direction.

As described above, when the magnetic sensor 10 is attached to the holding member 20, for example, the magnetic sensor 10 is moved from the first side S1 toward the second side S2, and is inserted between the extension portion 22 and the guide portion 23, and the protrusion 25 (second engaging portion 24) is engaged with the recess 14 (first engaging portion 13). At this time, the magnetic sensor 10 is inserted between the extension portion 22 and the guide portion 23 while being guided by the guide portion 23. The extension portion 22 and the guide portion 23 may be flexible, and when the magnetic sensor 10 is inserted between the extension portion 22 and the guide portion 23, the extension portion 22 and the guide portion 23 may be pressed by the magnetic sensor 10 and flexibly deformed outward in the Y direction. In a state in which the magnetic sensor 10 is attached to the holding member 20, the magnetic sensor 10 is disposed between the extension portion 22 and the guide portion 23, and is disposed in the opening portion 21c of the base portion 21.

A length L1 by which the extension portion 22 extends from the base portion 21 (a height of the extension portion 22 in the Z direction) is shorter than a length L2 by which the guide portion 23 extends from the base portion 21 (a height of the guide portion 23 in the Z direction). In this example, the length L1 is substantially half the length L2. Accordingly, the position at which the protrusion 25 provided at the tip portion of the extension portion 22 is engaged with the recess 14 can be set to substantially half the height of the guide portion 23, and the engaging pressure exerted by the protrusion 25 can act uniformly on the guide portion 23. In addition, in other words, the length L2 by which the guide portion 23 extends from the base portion 21 is longer than the length L1 by which the extension portion 22 extends from the base portion 21. Accordingly, when the magnetic sensor 10 is inserted between the extension portion 22 and the guide portion 23, the magnetic sensor 10 can be suitably guided by the guide portion 23, and the magnetic sensor 10 can be easily attached to the holding member 20.

### Functions and Effects

In the magnetic sensor unit 3, the first engaging (locking) portion 13 formed by the recess 14 is formed on the side surface 10c (outer surface) of the magnetic sensor 10, and the second engaging (locking) portion 24 formed by the protrusion 25 corresponding to the recess 14 is formed in the extension portion 22 of the holding member 20. Furthermore, the second engaging portion 24 is engaged with (locked to) the first engaging portion 13, as a result of which the magnetic sensor 10 is detachably held by the holding member 20. By adopting such a holding structure, the magnetic sensor 10 can be brought closer to the measurement target A, for example, compared to when the magnetic sensor 10 is held by being sandwiched between the holding members. In addition, since the magnetic sensor 10 is detachably held by the engagement between the first engaging portion 13 formed on the side surface 10c of the magnetic sensor 10 and the second engaging portion 24 formed in the extension portion 22, the magnetic sensor 10 can be easily attached and detached. Therefore, according to the magnetic sensor unit 3, the magnetic sensor 10 can be brought close to the measurement target A, and the magnetic sensor 10 can be easily attached and detached.

In addition, in the magnetic sensor unit 3, the magnetic sensor 10 can be attached to and detached from the holding member 20 solely by moving the magnetic sensor 10 along the Z direction with respect to the holding member 20 (namely, without spreading the holding members 20 with the fingers). Such a configuration also facilitates the attachment and detachment of the magnetic sensor 10. In addition, since the magnetic sensors 10 can be attached to and detached from the holding member 20 without using a tool, when the plurality of magnetic sensor units 3 are disposed (stacked) on the attachment member 2, there is no need to secure gaps between the magnetic sensor units 3 to allow the tool to pass therethrough. Therefore, the magnetic sensor units 3 can be disposed on the attachment member 2 with high density.

The holding member 20 includes the guide portion 23 extending from the base portion 21, and when the magnetic sensor 10 is attached to the holding member 20, the magnetic sensor 10 is guided by the guide portion 23. Accordingly, the magnetic sensor 10 can be easily attached to the holding member 20.

The guide portion 23 is disposed to sandwich (interpose) the magnetic sensor 10 between the extension portion 22 and the guide portion 23 in a state in which the magnetic sensor 10 is attached to the holding member 20. Accordingly, the magnetic sensor 10 can be more easily attached to the holding member 20.

The length L2 by which the guide portion 23 extends from the base portion 21 is longer than the length L1 by which the extension portion 22 extends from the base portion 21. Accordingly, when the magnetic sensor 10 is inserted between the extension portion 22 and the guide portion 23, the magnetic sensor 10 can be suitably guided by the guide portion 23, and the magnetic sensor 10 can be easily attached to the holding member 20.

The inclined surface 25b that guides the recess 14 of the first engaging portion 13 when the magnetic sensor 10 is attached to the holding member 20 and when the magnetic sensor 10 is removed from the holding member 20 is formed on the protrusion 25 of the second engaging portion 24. Accordingly, the magnetic sensor 10 can be easily attached to or removed from the holding member 20.

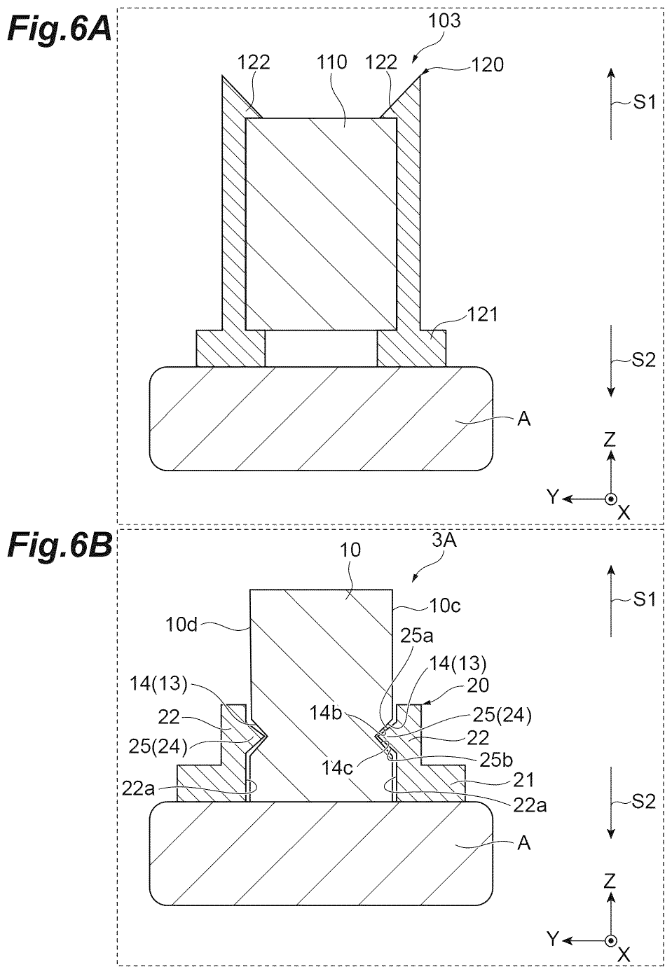

FIG. 6A is a cross-sectional view of a magnetic sensor unit 103 according to a comparative example, and FIG. 6B is a cross-sectional view of a magnetic sensor unit 3A according to a first modification example. Referring to FIGS. 6A and 6B, advantages of the magnetic sensor unit 3 according to the embodiment and the magnetic sensor unit 3A according to the first modification example will be described.

In the magnetic sensor unit 103 of the comparative example shown in FIG. 6A, no recess is formed on a side surface (outer surface) of a magnetic sensor 110. In the magnetic sensor unit 103, the magnetic sensor 110 is sandwiched between a base portion 121 and claw portions 122 of a holding member 120, so that the magnetic sensor 110 is held. Incidentally, as in the magnetic sensor 110, the shape of the magnetic sensor is typically a flat shape in which no unevenness is formed on the outer surface. The reason is that the smaller the magnetic sensor is, the closer the magnetic sensor can be brought to the measurement target A, which is advantageous from the viewpoint of improving sensitivity.

In the magnetic sensor unit 3A of the first modification example shown in FIG. 6B, the first engaging portion 13 (recess 14) is also formed on a side surface 10d in addition to the side surface 10c of the magnetic sensor 10. The side surface 10d is a surface on the side opposite the side surface 10c on which the first engaging portion 13 is formed. In the first modification example, the recess 14 is formed in a triangular shape in a cross section perpendicular to the X direction. The side surface 14b of the recess 14 is inclined toward the second side S2 as the side surface 14b approaches a bottom portion of the recess 14. The side surface 14c of the recess 14 is inclined toward the first side S1 as the side surface 14c approaches the bottom portion. Namely, in the magnetic sensor unit 3A of the first modification example, the side surface 14b and the side surface 14c are inclined surfaces. In the first modification example, the guide portion 23 is not provided, and a pair of the extension portions 22 are provided to interpose the magnetic sensor 10 therebetween. The second engaging portion 24 (protrusion 25) is formed in each of the extension portions 22.

As shown in FIG. 6A, in the magnetic sensor unit 103 of the comparative example, the magnetic sensor 110 is spaced apart from the measurement target A by the thickness of the base portion 121 in the Z direction. Since the magnetic field attenuates in proportion to the square of the distance, when the magnetic sensor 110 is spaced apart from the measurement target A, sufficient measurement sensitivity cannot be obtained, which is a risk. In addition, since the magnetic sensor 110 is held by being sandwiched between the holding member 120 from both sides in the Z direction, it is necessary to deform the claw portions 122 when the magnetic sensor 110 is attached and detached, thereby requiring time and effort for attachment and detachment. In addition, a cable connected to the magnetic sensor 110 may interfere with the claw portion 122, thereby causing damage to the cable, which is a risk.

Meanwhile, as shown in FIG. 6B, in the magnetic sensor unit 3A of the first modification example, since the magnetic sensor 10 is held by the engagement between the first engaging portion 13 formed on the outer surface of the magnetic sensor 10 and the second engaging portion 24 formed in the extension portion 22, the magnetic sensor 10 can be brought closer to the measurement target A compared to the case of the comparative example. For example, the magnetic sensor 10 can be held such that the magnetic sensor 10 comes into direct contact with the measurement target A. In addition, since the magnetic sensor 10 is detachably held by the engagement between the first engaging portion 13 and the second engaging portion 24, for example, by moving the magnetic sensor 10 toward the second side S2, the magnetic sensor 10 can be attached to the holding member 20, and the magnetic sensor 10 can be easily attached and detached. In addition, since there is no need to provide the claw portions 122 as in the comparative example, damage to the cable as described above can be suppressed. In addition, since there is no need to provide the claw portions 122, the holding member 20 can be made compact. These advantages of the first modification example are also achieved in the same manner in the magnetic sensor unit 3 according to the above-described embodiment.

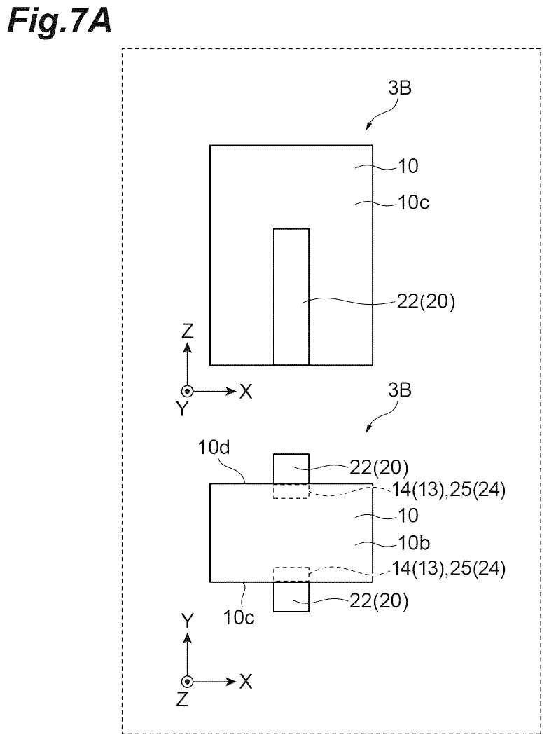

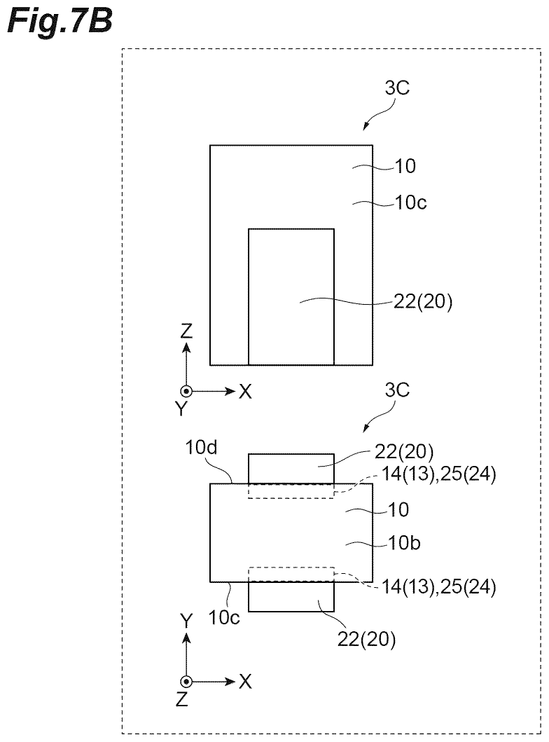

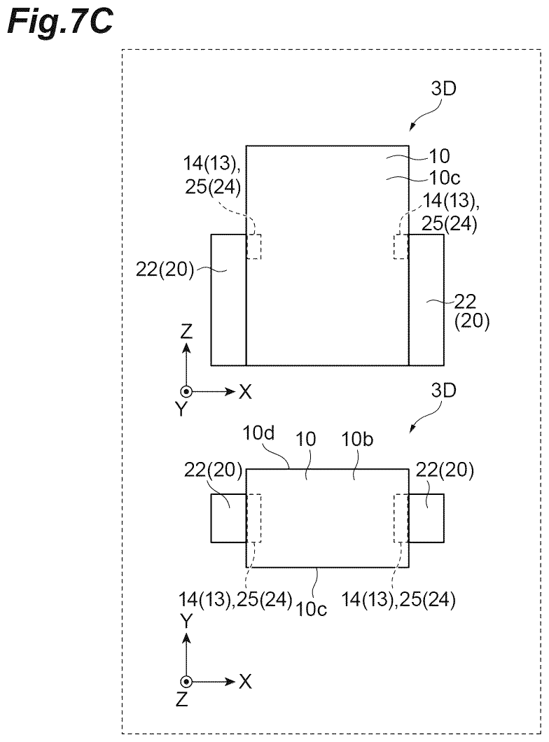

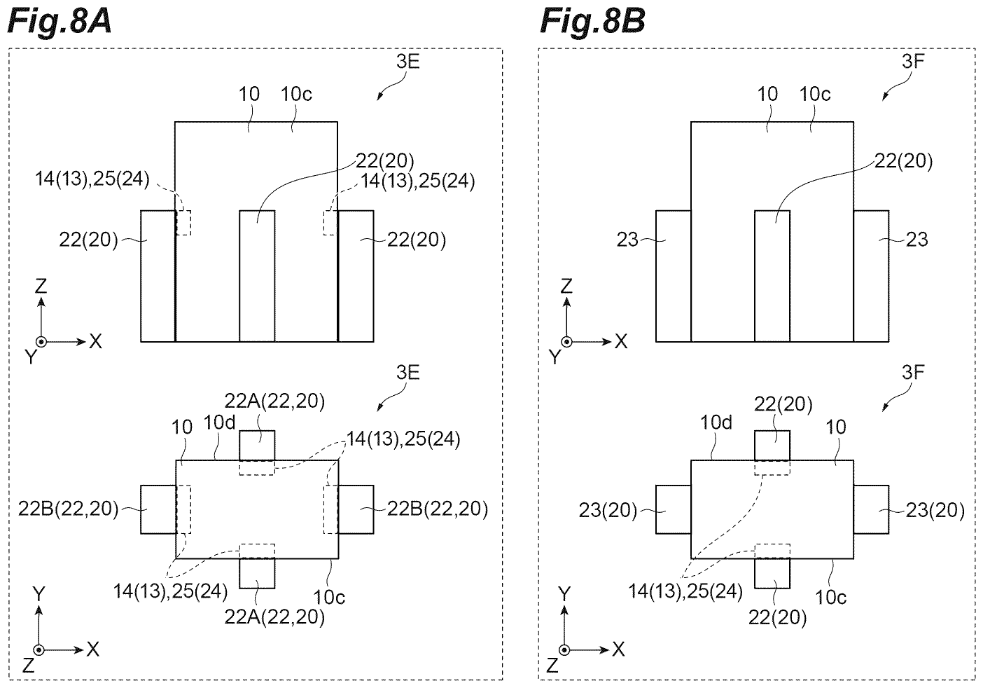

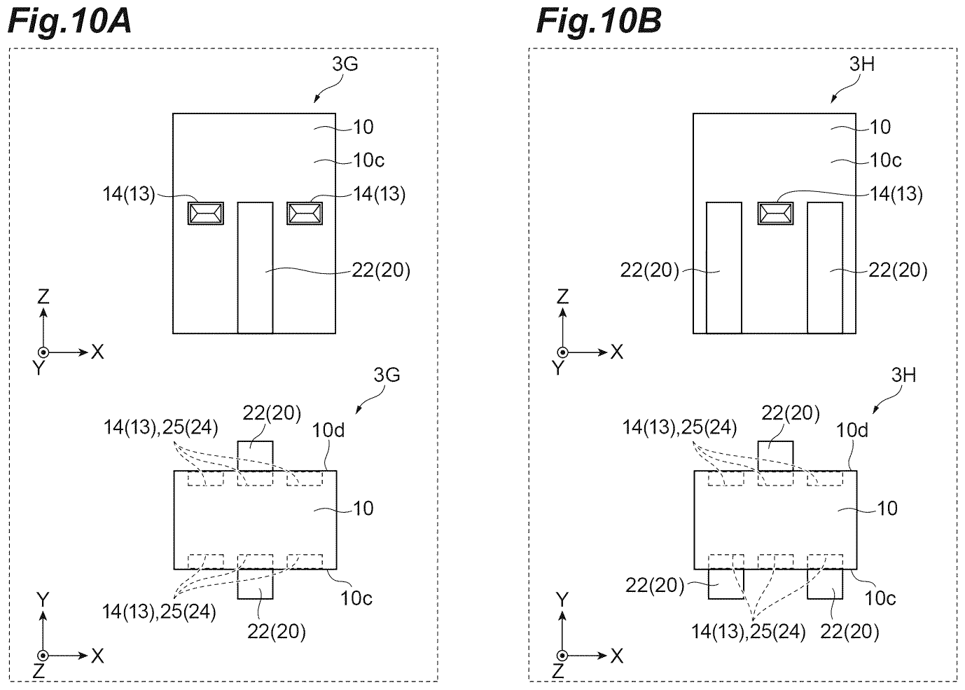

FIGS. 7A to 7C are views showing magnetic sensor units 3B to 3D according to second to fourth modification examples. In each view of FIGS. 7A to 7C, a side view is shown on the upper side, and a plan view is shown on the lower side. The same applies to FIGS. 8A, 8B, 10A and 10B to be described later.

The magnetic sensor unit 3B according to the second modification example shown in FIG. 7A and the magnetic sensor unit 3C according to the third modification example shown in FIG. 7B are configured similarly to the magnetic sensor unit 3A of the first modification example. In the second modification example and the third modification example, the extension portions 22, the first engaging portions 13 (recesses 14), and the second engaging portions 24 (protrusions 25) are each provided in pairs. The pair of extension portions 22 are disposed to interpose the magnetic sensor 10 therebetween in the Y direction perpendicular to the long sides of the magnetic sensor 10. The extension portion 22, the first engaging portion 13, and the second engaging portion 24 of the third modification example are formed to be wider than those of the second modification example. For example, in the example of FIG. 7B, in the X direction, the widths of the extension portion 22, the first engaging portion 13, and the second engaging portion 24 are larger than half the width of the magnetic sensor 10. In this case, the magnetic sensor 10 can be more stably held by the holding member 20.

In the magnetic sensor unit 3D according to the fourth modification example shown in FIG. 7C, a pair of the extension portions 22 are disposed to interpose the magnetic sensor 10 therebetween in the X direction perpendicular to the short sides of the magnetic sensor 10. In other respects, the fourth modification example is configured similarly to, for example, the magnetic sensor unit 3A of the first modification example. In the magnetic sensor units 3B to 3D according to the second to fourth modification examples as well, similarly to the above-described embodiment, the magnetic sensor 10 can be brought close to the measurement target, and the magnetic sensor 10 can be easily attached and detached. In addition, for example, compared to three or more extension portions 22 (the first engaging portions 13 and the second engaging portions 24) are provided, the number of the engaging portions can be reduced, and the occupied area when viewed in the Z direction can be reduced.

In a magnetic sensor unit 3E according to a fifth modification example shown in FIG. 8A, four extension portions 22, four first engaging portions 13, and four second engaging portions 24 are provided. The four extension portions 22 are composed of a pair of extension portions 22A and a pair of extension portions 22B. The pair of extension portions 22A are disposed to interpose the magnetic sensor 10 therebetween in the Y direction perpendicular to the long sides of the magnetic sensor 10. The pair of extension portions 22B are disposed to interpose the magnetic sensor 10 therebetween in the X direction perpendicular to the short sides of the magnetic sensor 10. Namely, the four extension portions 22 are disposed to face four respective outer surfaces of the magnetic sensor 10 when viewed in the Z direction. In other respects, the fifth modification example is configured similarly to, for example, the magnetic sensor unit 3A of the first modification example. In the magnetic sensor unit 3E according to the fifth modification example as well, similarly to the above-described embodiment, the magnetic sensor 10 can be brought close to the measurement target, and the magnetic sensor 10 can be easily attached and detached. In addition, the magnetic sensor 10 can be stably held in two directions, the X direction and the Y direction, by the holding member 20.

A magnetic sensor unit 3F according to a sixth modification example shown in FIG. 8B includes a pair of the extension portions 22 disposed to interpose the magnetic sensor 10 therebetween in the Y direction, and a pair of the guide portions 23 disposed to interpose the magnetic sensor 10 therebetween in the X direction. In other respects, the sixth modification example is configured similarly to, for example, the magnetic sensor unit 3A of the first modification example. When the magnetic sensor 10 is attached to the holding member 20, the magnetic sensor 10 is guided by the pair of guide portions 23. In the magnetic sensor unit 3F according to the sixth modification example as well, similarly to the above-described embodiment, the magnetic sensor 10 can be brought close to the measurement target, and the magnetic sensor 10 can be easily attached and detached. In addition, since the pair of extension portions 22 are disposed to interpose the magnetic sensor 10 therebetween, the magnetic sensor 10 can be reliably held by the holding member 20, and since the pair of guide portions 23 are disposed to interpose the magnetic sensor 10 therebetween, the magnetic sensor 10 can be easily attached to the holding member 20. In addition, similarly to the magnetic sensor units 3E of the fifth modification example, the magnetic sensor 10 can be stably held in two directions, the X direction and the Y direction, by the holding member 20.

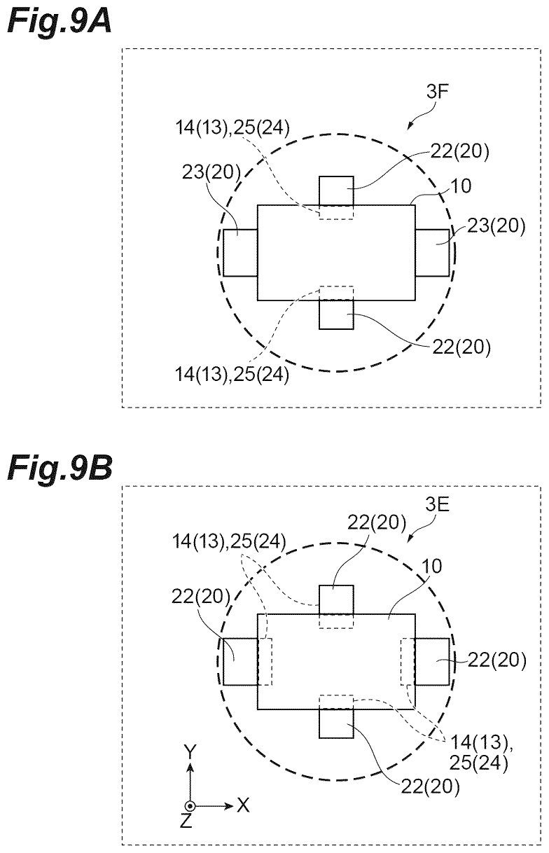

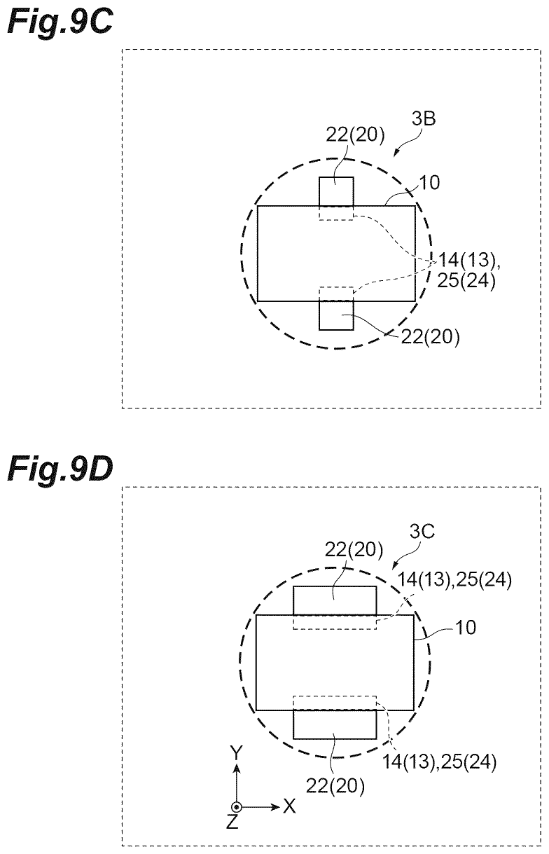

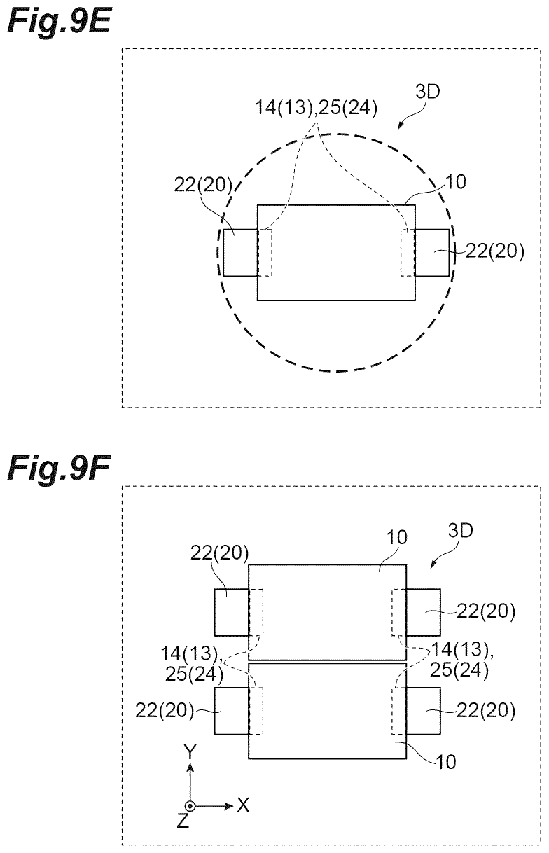

Referring to FIGS. 9A to 9F, in the magnetic sensor units 3B to 3F according to the second to sixth modification examples, the occupied areas when viewed in the Z direction will be compared. In FIG. 9A, a plan view of the magnetic sensor unit 3F according to the sixth modification example is shown. In FIG. 9B, a plan view of the magnetic sensor unit 3E according to the fifth modification example is shown. In FIG. 9C, a plan view of the magnetic sensor unit 3B according to the second modification example is shown. In FIG. 9D, a plan view of the magnetic sensor unit 3C according to the third modification example is shown. In FIGS. 9E and 9F, plan views of the magnetic sensor unit 3D according to the fourth modification example are shown. In FIG. 9E, one magnetic sensor unit 3D is shown. In FIG. 9F, a state in which two magnetic sensor units 3D are aligned along the Y direction is shown.

In FIGS. 9A to 9E, a circle having a diameter corresponding to the length of a longest portion when viewed in the Z direction is shown by a dashed line on each plan view of the magnetic sensor units 3B to 3F. The density at which a plurality of the magnetic sensor units 3 are disposed (stacked) on the attachment member 2 can be determined by the size (occupied area) of the circle. Namely, the smaller the size of the circle is and the smaller the occupied area is, the more densely a plurality of the magnetic sensor units 3 can be disposed. As shown in FIGS. 9A to 9F, in the magnetic sensor units 3B and 3C according to the second and third modification examples (FIGS. 9C and 9D), since the pair of extension portions 22 are disposed to interpose the magnetic sensor 10 therebetween in the Y direction perpendicular to the long sides of the magnetic sensor 10, the occupied area can be further reduced compared to the magnetic sensor units 3D to 3F according to the fourth to sixth modification examples (FIGS. 9A, 9B, 9E and 9F). Therefore, in the magnetic sensor units 3B and 3C, a plurality of the magnetic sensor units 3 can be disposed with high density. Meanwhile, as shown in FIG. 9F, in the magnetic sensor unit 3D according to the fourth modification example, since the pair of extension portions 22 are disposed to interpose the magnetic sensor 10 therebetween in the X direction perpendicular to the short sides of the magnetic sensor 10, when a plurality of the magnetic sensor units 3 are aligned along the Y direction, the dead space between the plurality of magnetic sensor units 3 can be reduced to improve the disposition efficiency, and a plurality of the magnetic sensor units 3 can be disposed with high density.

In a magnetic sensor unit 3G according to a seventh modification example shown in FIG. 10A, a plurality of the first engaging portions 13 (recesses 14) are formed in the magnetic sensor 10. In this example, three first engaging portions 13 aligned along the X direction (the direction perpendicular to the extending direction of the extension portion 22) are formed on each of the side surface 10c and the side surface 10d of the magnetic sensor 10. Then, the second engaging portion 24 (protrusion 25) is selectively engaged with any one of the plurality of first engaging portions 13. In the example of FIG. 10A, the second engaging portion 24 is engaged with the first engaging portion 13 located at the center among the three first engaging portions 13. In other respects, the seventh modification example is configured similarly to, for example, the magnetic sensor unit 3A of the first modification example.

In the magnetic sensor unit 3G according to the seventh modification example as well, similarly to the above-described embodiment, the magnetic sensor 10 can be brought close to the measurement target, and the magnetic sensor 10 can be easily attached and detached. In addition, the position at which the magnetic sensor 10 is held by the holding member 20 can be adjusted by changing the first engaging portion 13 with which the second engaging portion 24 is engaged. In this example, the position at which the magnetic sensor 10 is held by the holding member 20 can be adjusted in the X direction.

A magnetic sensor unit 3H according to an eighth modification example shown in FIG. 10B differs from the magnetic sensor unit 3G of the seventh modification example in that two extension portions 22 are provided on one side of the magnetic sensor 10 in the Y direction and one extension portion 22 is provided on the other side of the magnetic sensor 10 in the Y direction. The two extension portions 22 on the one side in the Y direction are engaged with two respective first engaging portions 13 located at both ends among three first engaging portions 13 formed on the side surface 10c. In other respects, the eighth modification example is configured similarly to, for example, the magnetic sensor unit 3A of the first modification example.

In the magnetic sensor unit 3H according to the eighth modification example as well, similarly to the above-described embodiment, the magnetic sensor 10 can be brought close to the measurement target, and the magnetic sensor 10 can be easily attached and detached. In addition, the magnetic sensor 10 can be stably held by the three extension portions 22 and the second engaging portions 24.

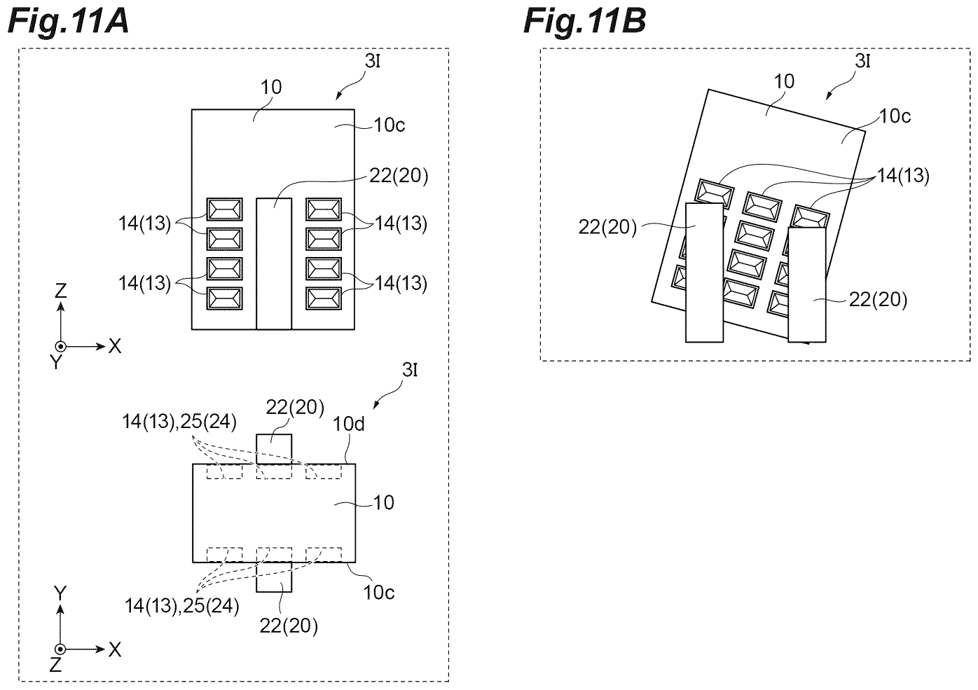

In a magnetic sensor unit 3I according to a ninth modification example shown in FIG. 11A, a plurality of the first engaging portions 13 (recesses 14) are disposed in alignment along each of the X direction and the Z direction. Specifically, 12 first engaging portions 13 are formed on each of the side surface 10c and the side surface 10d of the magnetic sensor 10. In this example, the 12 first engaging portions 13 are disposed in alignment in three rows along the X direction and four rows along the Z direction. In other respects, the ninth modification example is configured similarly to, for example, the magnetic sensor unit 3A of the first modification example.

In the magnetic sensor unit 3I according to the ninth modification example as well, similarly to the above-described embodiment, the magnetic sensor 10 can be brought close to the measurement target, and the magnetic sensor 10 can be easily attached and detached. In addition, the position at which the magnetic sensor 10 is held by the holding member 20 can be adjusted in the X direction and the Z direction. Furthermore, as shown in FIG. 11B, the magnetic sensor 10 can be disposed obliquely with respect to the Z direction.

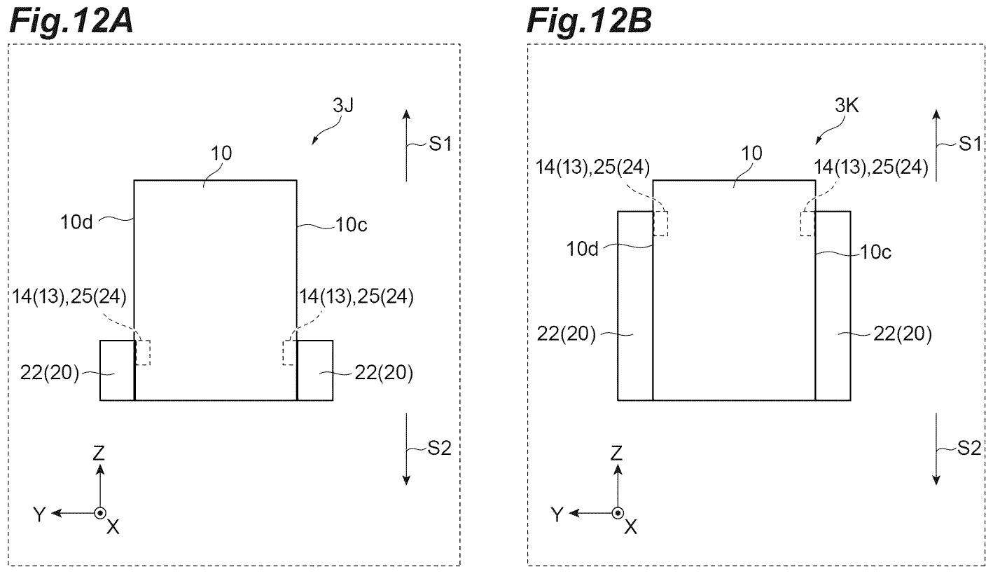

In a magnetic sensor unit 3J according to a tenth modification example shown in FIG. 12A, the engaging position of the first engaging portions 13 and the second engaging portions 24 is disposed on the second side S2 (base end side) of the magnetic sensor 10 in the Z direction. Specifically, the first engaging portions 13 and the second engaging portions 24 are disposed on the second side S2 with respect to the center of the magnetic sensor 10 in the Z direction. In other respects, the tenth modification example is configured similarly to, for example, the magnetic sensor unit 3A of the first modification example.

In the magnetic sensor unit 3J according to the tenth modification example as well, similarly to the above-described embodiment, the magnetic sensor 10 can be brought close to the measurement target, and the magnetic sensor 10 can be easily attached and detached. In addition, the length of the extension portions 22 can be shortened, and the magnetic sensor unit 3 can be made compact.

In a magnetic sensor unit 3K according to an eleventh modification example shown in FIG. 12B, the engaging position of the first engaging portions 13 and the second engaging portions 24 is disposed on the first side S1 (tip side) of the magnetic sensor 10 in the Z direction. Specifically, the first engaging portions 13 and the second engaging portions 24 are disposed on the first side S1 with respect to the center of the magnetic sensor 10 in the Z direction. In other respects, the eleventh modification example is configured similarly to, for example, the magnetic sensor unit 3A of the first modification example.

In the magnetic sensor unit 3K according to the eleventh modification example as well, similarly to the above-described embodiment, the magnetic sensor 10 can be brought close to the measurement target, and the magnetic sensor 10 can be easily attached and detached. In addition, the extension portions 22 can be lengthened, and the magnetic sensor 10 can be stably held by the holding member 20.

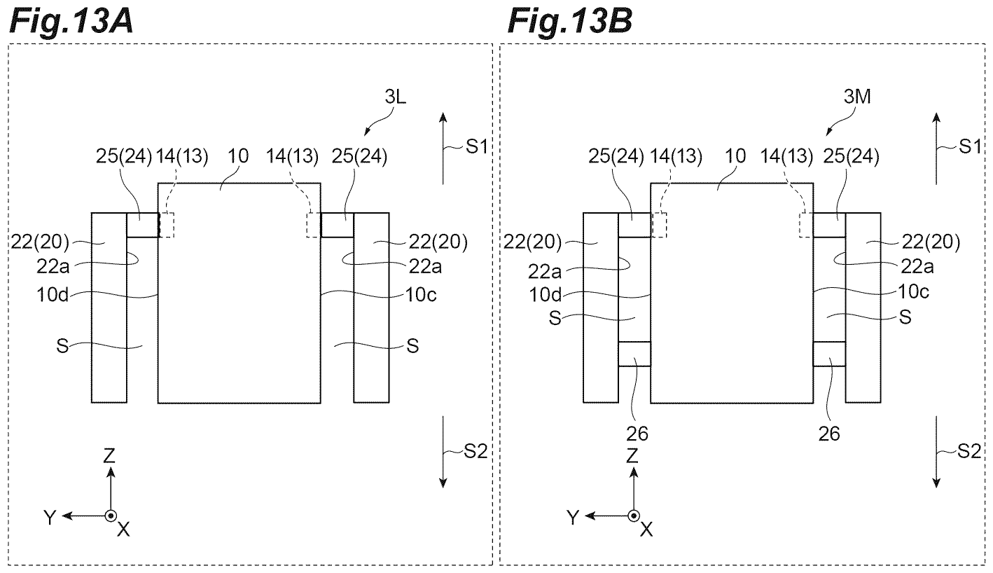

In a magnetic sensor unit 3L according to a twelfth modification example shown in FIG. 13A, the holding member 20 holds the magnetic sensor 10 such that gaps S are provided between the extension portions 22 and the magnetic sensor 10. Specifically, the gaps S are formed between the surfaces 22a of the extension portions 22 that face the magnetic sensor 10 and the side surfaces 10c and 10d of the magnetic sensor 10. In other respects, the twelfth modification example is configured similarly to, for example, the magnetic sensor unit 3A of the first modification example.

In the magnetic sensor unit 3L according to the twelfth modification example as well, similarly to the above-described embodiment, the magnetic sensor 10 can be brought close to the measurement target, and the magnetic sensor 10 can be easily attached and detached. In addition, for example, the magnetic sensor 10 can be cooled by allowing cooling air to flow through the gaps S.

A magnetic sensor unit 3M according to a thirteenth modification example shown in FIG. 13B differs from the magnetic sensor unit 3L according to the twelfth modification example in that each of the extension portions 22 includes a guide protrusion 26. The guide protrusion 26 protrudes from the surface 22a of the extension portion 22, which faces the magnetic sensor 10, toward the magnetic sensor 10. In this example, the guide protrusion 26 is disposed on the second side S2 with respect to the second engaging portion 24. When the magnetic sensor 10 is attached to the holding member 20, the guide protrusion 26 guides the magnetic sensor 10. In other respects, the thirteenth modification example is configured similarly to, for example, the magnetic sensor unit 3A of the first modification example.

In the magnetic sensor unit 3M according to the thirteenth modification example as well, similarly to the above-described embodiment, the magnetic sensor 10 can be brought close to the measurement target, and the magnetic sensor 10 can be easily attached and detached. In addition, the magnetic sensor 10 can be easily attached to the holding member 20 by providing the guide protrusion 26.

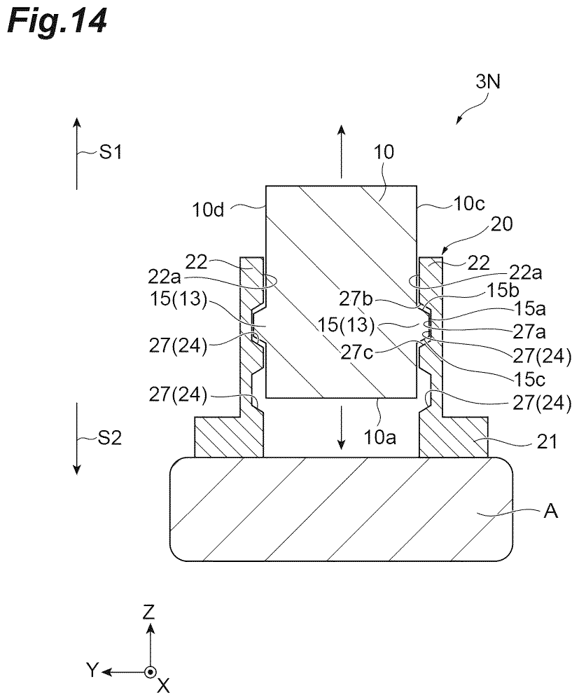

A magnetic sensor unit 3N according to a fourteenth modification example shown in FIG. 14 differs from the magnetic sensor unit 3A of the first modification example in that the first engaging portion 13 is formed by a protrusion 15, the second engaging portion 24 is formed by a recess 27, and a plurality of (in this example, two) the second engaging portions 24 are provided in each of the extension portions 22. The protrusion 15 is formed in a trapezoidal shape in a cross section perpendicular to the X direction. The protrusion 15 has a top surface 15a, an inclined surface 15b, and an inclined surface 15c. The top surface 15a is a flat surface having a rectangular shape and extending along the X direction and the Z direction. The inclined surface 15b is a surface on the first side S1, and is inclined toward the second side S2 as the inclined surface 15b approaches the tip side of the protrusion 15. The inclined surface 15c is a surface on the second side S2, and is inclined toward the first side S1 as the inclined surface 15c approaches the tip side of the protrusion 15.

The second engaging portion 24 is formed by the recess 27 corresponding to the protrusion 15 of the first engaging portion 13. The recess 27 is formed in a trapezoidal shape in a cross section perpendicular to the X direction. A side surface 27b of the recess 27 is inclined toward the second side S2 as the side surface 27b approaches a bottom surface 27a side of the recess 27. A side surface 27c of the recess 27 is inclined toward the first side S1 as the side surface 27c approaches the bottom surface 27a side of the recess 27. Namely, the side surfaces 27b and 27c are inclined surfaces. The first engaging portion 13 is selectively engaged with any one of the plurality of second engaging portions 24.

When the magnetic sensor 10 is attached to the holding member 20, the magnetic sensor 10 is moved toward the second side S2, and the inclined surface 15b of the protrusion 15 slides on the side surface 27b of the recess 27, so that the protrusion 15 enters the recess 27 while the protrusion 15 is guided by the recess 27. When the protrusion 15 is engaged with another recess 27 disposed on the second side S2, the magnetic sensor 10 is further moved toward the second side S2, and the inclined surface 15c of the protrusion 15 slides on the side surface 27c of the recess 27, so that the protrusion 15 comes out of the recess 27 while the protrusion 15 is guided by the recess 27. In addition, when the magnetic sensor 10 is removed from the holding member 20, the magnetic sensor 10 is moved toward the first side S1, and the inclined surface 15b of the protrusion 15 slides on the side surface 27b of the recess 27, so that the protrusion 15 comes out of the recess 27 while the protrusion 15 is guided by the recess 27.

In the magnetic sensor unit 3N according to the fourteenth modification example as well, similarly to the above-described embodiment, the magnetic sensor 10 can be brought close to the measurement target, and the magnetic sensor 10 can be easily attached and detached. In addition, the position at which the magnetic sensor 10 is held by the holding member 20 can be adjusted by changing the second engaging portion 24 with which the first engaging portion 13 is engaged. In this example, the position at which the magnetic sensor 10 is held by the holding member 20 can be adjusted in the Z direction.

The present disclosure is not limited to the embodiment and the modification examples described above. For example, the material and shape of each configuration are not limited to the material and shape described above, and various materials and shapes can be adopted. The length L2 by which the guide portion 23 extends from the base portion 21 may be shorter than the length L1 by which the extension portion 22 extends from the base portion 21, or may be equal to the length L1. The shape of the magnetic sensor 10 when viewed in the Z direction may be any shape, for example, a square shape. The shape of the base portion 21 (holding member 20) when viewed in the Z direction may be any shape, for example, a square shape or a rectangular shape.

The first engaging portion 13 may be formed by the recess 14 as in the above-described embodiment, or may be formed by the protrusion 15 as in the fourteenth modification example. The first engaging portion 13 may include both a recess and a protrusion. The second engaging portion 24 may be formed by the protrusion 25 as in the above-described embodiment, or may be formed by the recess 27 as in the fourteenth modification example. The second engaging portion 24 may include both a recess and a protrusion.

In the above-described embodiment, the inclined surfaces 25a and 25b are formed on the second engaging portion 24 (protrusion 25), and in the first modification example, the side surfaces 14b and 14c are formed on the first engaging portion 13 (recess 14) as inclined surfaces, and the inclined surfaces 25a and 25b are formed on the second engaging portion 24 (protrusion 25); however, inclined surfaces may be formed only on the first engaging portion 13, and inclined surfaces may not be formed on the second engaging portion 24. Alternatively, inclined surfaces may not be formed on both the first engaging portion 13 and the second engaging portion 24. The extension portion 22 may be formed, for example, in a tubular shape to surround the magnetic sensor 10 when viewed in the Z direction.

In the above-described embodiment, the magnetic sensor 10 protrudes from the attachment member 2 toward the side opposite the measurement target A; however, the magnetic sensor 10 may protrude from the attachment member 2 toward the measurement target A side. In this case, for example, the extension portion 22 of the holding member 20 may extend from the base portion 21 toward the measurement target A side. In this case, the measurement surface of the magnetic sensor 10 may face the measurement target A on the tip side of the extension portion 22.

The magnetic sensor 10 is not limited to an optically pumped magnetometer, and may be a tunneling magnetoresistance (TMR) sensor, a fluxgate sensor, or the like. The measurement target A may be a portion of a human other than the brain (head 4) (for example, the heart, the spinal cord, or the like). In this case, the shape of the attachment member 2 may be changed to suit an attachment target portion. The measurement target A may be a living body, or may be, for example, an industrial product or the like.

What is claimed is:

1. A magnetic sensor unit, comprising:
a magnetic sensor; and
a holding member that detachably holds the magnetic sensor,
wherein a first engaging portion formed by at least one of a recess and a protrusion is formed on an outer surface of the magnetic sensor,
the holding member includes a base portion and an extension portion extending from the base portion, the extension portion being formed with a second engaging portion formed by at least one of a protrusion corresponding to the recess and a recess corresponding to the protrusion, and
the magnetic sensor is detachably held by the holding member by the second engaging portion being engaged with the first engaging portion.

2. The magnetic sensor unit according to claim 1,
wherein the holding member further includes a guide portion extending from the base portion, and
the magnetic sensor is guided by the guide portion while the magnetic sensor is being attached to the holding member.

3. The magnetic sensor unit according to claim 2,
wherein the guide portion is disposed to interpose the magnetic sensor between the extension portion and the guide portion.

4. The magnetic sensor unit according to claim 2,
wherein a length by which the guide portion extends from the base portion is longer than a length by which the extension portion extends from the base portion.

5. The magnetic sensor unit according to claim 1,
wherein at least one of the first engaging portion and the second engaging portion is formed with an inclined surface that guides the first engaging portion or the second engaging portion while the magnetic sensor is being attached to the holding member and/or while the magnetic sensor is being removed from the holding member.

6. The magnetic sensor unit according to claim 1,
wherein the magnetic sensor is formed in a rectangular shape when viewed in an extending direction of the extension portion,
a pair of the extension portions, a pair of the first engaging portions, and a pair of the second engaging portions are provided, and
the pair of extension portions are disposed to interpose the magnetic sensor between the pair of extension portions in a direction perpendicular to long sides of the magnetic sensor.

7. The magnetic sensor unit according to claim 1,
wherein the magnetic sensor is formed in a rectangular shape when viewed in an extending direction of the extension portion,
a pair of the extension portions, a pair of the first engaging portions, and a pair of the second engaging portions are provided, and
the pair of extension portions are disposed to interpose the magnetic sensor between the pair of extension portions in a direction perpendicular to short sides of the magnetic sensor.

8. The magnetic sensor unit according to claim 1,
wherein the magnetic sensor is formed in a square shape or a rectangular shape when viewed in an extending direction of the extension portion,
four each of the extension portions, the first engaging portions, and the second engaging portions are provided, and
the four extension portions are disposed to face four respective outer surfaces of the magnetic sensor when viewed in the extending direction.

9. The magnetic sensor unit according to claim 1,
wherein the magnetic sensor is formed in a square shape or a rectangular shape when viewed in an extending direction of the extension portion,
a pair of the extension portions, a pair of the first engaging portions, and a pair of the second engaging portions are provided,
the pair of extension portions are disposed to interpose the magnetic sensor between the pair of extension portions in a first direction perpendicular to the extending direction,
the holding member further includes a pair of guide portions extending from the base portion,
the magnetic sensor is guided by the pair of guide portions while the magnetic sensor is being attached to the holding member, and
the pair of guide portions are disposed to interpose the magnetic sensor between the pair of guide portions in a second direction perpendicular to the extending direction and the first direction.

10. The magnetic sensor unit according to claim 1,
wherein an engaging position of the first engaging portion and the second engaging portion is located on a base end side of the magnetic sensor in an extending direction of the extension portion.

11. The magnetic sensor unit according to claim 1,
wherein an engaging position of the first engaging portion and the second engaging portion is located on a tip side of the magnetic sensor in an extending direction of the extension portion.

12. The magnetic sensor unit according to claim 1,
wherein a plurality of the first engaging portions are formed in the magnetic sensor, and
the second engaging portion is selectively engaged with any one of the plurality of first engaging portions.

13. The magnetic sensor unit according to claim 12,
wherein the plurality of first engaging portions are aligned along a direction perpendicular to an extending direction of the extension portion.

14. The magnetic sensor unit according to claim 12,
wherein the plurality of first engaging portions are aligned along a direction parallel to an extending direction of the extension portion.

15. The magnetic sensor unit according to claim 1,
wherein a plurality of the second engaging portions are formed in the extension portion, and
the first engaging portion is selectively engaged with any one of the plurality of second engaging portions.

16. The magnetic sensor unit according to claim 1,
wherein the holding member holds the magnetic sensor such that a gap is provided between the extension portion and the magnetic sensor.
